(19) United States
(12) Patent Application Publication
(10) Pub. No.: US 2026/0123145 A1
(43) Pub. Date: Apr. 30, 2026

(54) DISPLAY PANEL, METHOD FOR PREPARING DISPLAY PANEL, AND ELECTRONIC DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Jingxian XING, Kunshan (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/373,657

(22) Filed: Oct. 29, 2025

(30) Foreign Application Priority Data
Oct. 30, 2024 (CN) 202411537540.3

(51) Int. Cl. H10H 29/49; H10H 29/01; H10H 29/37; H10K 59/12; H10K 59/122; H10K 59/126; H10K 59/131; H10K 59/40

(52) U.S. Cl. CPC H10H 29/49; H10H 29/012; H10H 29/37; H10K 59/1201; H10K 59/122; H10K 59/126; H10K 59/131; H10K 59/40

(57) ABSTRACT

The embodiments of the present application provide a display panel, a method for preparing the display panel, and an electronic device, which relate to the field of display technology. The display panel includes a display area and at least one non-display area partially surrounding the display area. The display panel includes a substrate, an array signal layer, an isolation structure, a light-emitting unit, a touch layer, and a shielding layer. The array signal layer includes a plurality of signal traces. The isolation structure is located on a side of the array signal layer away from the substrate, and the isolation structure encloses to form isolation openings. The touch layer includes touch traces, and at least one touch traces are located in the non-display area. The shielding layer is located between the touch layer and the array signal layer, and the shielding layer includes shielding traces.

### CROSS REFERENCE

This present disclosure claims priorities to Chinese Patent Application No. 202411537540.3, filed on Oct. 30, 2024, entitled “Display Panel, Method for Preparing Display Panel, and Electronic Device”, which is incorporated herein by reference in its entirety.

### FIELD

The present application relates to the field of display technologies, and in particular, to a display panel, a method for preparing the display panel, and an electronic device.

### BACKGROUND

Flat panel display devices based on technologies such as Organic Light Emitting Diodes (OLEDs) and Light Emitting Diodes (LEDs) are widely used in various consumer electronic products such as mobile phones, televisions, laptops, and desktop computers due to their advantages of high image quality, low power consumption, thin profile, and wide application range, and have become mainstream in display panels.

However, display panels still have some issues that need to be resolved.

### SUMMARY

To overcome the technical problems mentioned in the above technical background, embodiments of the present application provide a display panel, the display panel comprising a display area and a non-display area at least partially surrounding the display area, the display panel comprising: a substrate; an array signal layer located on one side of the substrate, the array signal layer comprising a plurality of signal traces, at least one of the signal traces being located in the non-display area; an isolation structure located on a side of the array signal layer away from the substrate, the isolation structure enclosing to form isolation openings; a light-emitting unit at least partially located within the isolation openings; a touch layer located on a side of the light-emitting unit away from the substrate, the touch layer comprising touch traces, at least one of the touch traces being located in the non-display area; a shielding layer located between the touch layer and the array signal layer, the shielding layer comprising shielding traces, the shielding traces being located in the non-display area, and an orthographic projection of the touch traces on the substrate at least partially overlapping with an orthographic projection of the shielding traces on the substrate.

In some possible implementations, the present application further provides an electronic device, the electronic device comprising the display panel described in the present application, or comprising a display panel prepared by the method for preparing the display panel described in the present application.

Compared with the prior art, the present application has the following beneficial effects: The display panel, method for preparing the display panel, and electronic device provided by the present application can shield mutual signal interference between touch traces and signal traces by arranging a shielding layer between the touch layer and the array signal layer in the non-display area, thereby improving the touch performance and display performance of the display panel.

### BRIEF DESCRIPTION OF THE DRAWINGS

In order to more clearly illustrate the technical solutions of the embodiments of the present application, the following will briefly introduce the drawings required for the embodiments. It should be understood that the following drawings only show some embodiments of the present application and therefore should not be considered as limiting the scope. For those of ordinary skill in the art, other related drawings can be obtained based on these drawings without creative effort.

FIG. 1 is a top view schematic diagram of a display panel provided by an embodiment of the present application;

FIG. 2 is a first cross-sectional schematic diagram of A-A in FIG. 1 provided by an embodiment of the present application;

FIG. 3 is a second cross-sectional schematic diagram of A-A in FIG. 1 provided by an embodiment of the present application;

FIG. 4 is a third cross-sectional schematic diagram of A-A in FIG. 1 provided by an embodiment of the present application;

FIG. 5 is a fourth cross-sectional schematic diagram of A-A in FIG. 1 provided by an embodiment of the present application;

FIG. 6 is a fifth cross-sectional schematic diagram of A-A in FIG. 1 provided by an embodiment of the present application;

FIG. 7 is a sixth cross-sectional schematic diagram of A-A in FIG. 1 provided by an embodiment of the present application;

FIG. 8 is a seventh cross-sectional schematic diagram of A-A in FIG. 1 provided by an embodiment of the present application;

FIG. 9 is an eighth cross-sectional schematic diagram of A-A in FIG. 1 provided by an embodiment of the present application;

FIG. 10 is a flowchart schematic diagram of a method for preparing a display panel provided by an embodiment of the present application;

FIG. 11 is a cross-sectional schematic diagram of sequentially forming a third conductive layer, a first planarization layer, a fourth conductive layer, and a second planarization layer on a side of the array signal layer away from the substrate provided by an embodiment of the present application;

FIG. 12 is a cross-sectional schematic diagram of forming a first electrode and a first shielding layer on a side of the second planarization layer away from the substrate provided by an embodiment of the present application;

FIG. 13 is a cross-sectional schematic diagram of sequentially forming a pixel definition material layer and an isolation material layer on a side of the first electrode away from the substrate provided by an embodiment of the present application;

FIG. 14 is a cross-sectional schematic diagram after patterning the isolation material layer provided by an embodiment of the present application;

FIG. 15 is a cross-sectional schematic diagram after patterning the pixel definition material layer provided by an embodiment of the present application.

Reference numerals: 1, substrate; 2, array signal layer; 201, signal trace; 3, shielding layer; 301, first shielding structure; 302, second shielding structure; 31, first shielding trace; 311, first exhaust hole; 32, second shielding trace; 321, second exhaust hole; 33, third shielding trace; 34, fourth shielding trace; 341, fifth exhaust hole; 4, touch layer; 41, touch trace; 5, isolation structure; 51, first isolation portion; 52, second isolation portion; 53, third isolation portion; 6, isolation opening; 7, second electrode; 8, light-emitting portion; 9, first electrode; 10, light-emitting unit; 11, first insulating layer; 111, third exhaust hole; 112, fourth exhaust hole; 12, pixel definition layer; 121, pixel opening; 13, first planarization layer; 15, second planarization layer; 16, first conductive layer; 17, second conductive layer; 18, third conductive layer; 19, fourth conductive layer; 20, encapsulation unit; 21, second encapsulation layer; 22, third encapsulation layer; 23, pixel definition material layer; 24, isolation material layer.

### DETAILED DESCRIPTION

To make the objectives, technical solutions, and advantages of the embodiments of the present application clearer, the following will clearly and completely describe the technical solutions in the embodiments of the present application in conjunction with the accompanying drawings. Obviously, the described embodiments are only a part of the embodiments of the present application, not all of them. The components of the embodiments of the present application described and illustrated in the accompanying drawings herein can be arranged and designed in various configurations.

Therefore, the following detailed description of the embodiments of the present application provided in the accompanying drawings is not intended to limit the scope of the claimed application but merely represents selected embodiments of the present application. Based on the embodiments of the present application, all other embodiments obtained by those of ordinary skill in the art without creative effort fall within the scope of protection of the present application.

It should be noted that similar reference numerals and letters in the following drawings indicate similar items. Therefore, once an item is defined in one drawing, it does not require further definition and explanation in subsequent drawings.

In the description of the present application, it should be noted that the orientation or positional relationships indicated by terms such as “center,” “upper,” “lower,” “vertical,” “horizontal,” “inner,” and “outer” are based on the orientation or positional relationships shown in the drawings or the customary orientation or positional relationships when the product of the invention is used. These terms are used only to facilitate the description of the present application and simplify the description, and do not indicate or imply that the referred device or element must have a specific orientation or be constructed and operated in a specific orientation. Therefore, they should not be construed as limitations on the present application. In addition, terms such as “first,” “second,” and “third” are used only for descriptive purposes and should not be construed as indicating or implying relative importance.

It should be noted that, in the absence of conflict, different features in the embodiments of the present application can be combined with each other.

Increasing the density of light-emitting units (i.e., pixel density) in a display panel is an important way to improve display performance. However, display panels manufactured using Fine Metal Mask (FMM) technology are currently limited by technical constraints and cannot further increase the density of light-emitting units. Through long-term research, the inventors have found that to solve the technical problem of the inability to further increase the density of light-emitting units, isolation structures are arranged in some display panels. When the light-emitting material layer and the second electrode are deposited as entire layers, the light-emitting material layer and the second electrode can be disconnected at the isolation structures. By performing multiple depositions and multiple etching processes (i.e., light-emitting unit patterning), light-emitting units of different colors can be formed in different isolation openings.

Among them, patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A disclose relevant technical solutions for isolation structures, the contents of which are incorporated herein by reference for reference.

In related art, a display panel includes a substrate, an array signal layer located on one side of the substrate, an isolation structure located on the side of the array signal layer away from the substrate, a light-emitting unit located within isolation openings formed by the isolation structure, and a touch layer located on the side of the light-emitting unit away from the substrate. The display panel includes a display area and a non-display area. Some touch traces of the touch layer and some signal traces of the array signal layer are located in the non-display area. Signals between the touch traces and the signal traces in the non-display area interfere with each other, thereby affecting the touch performance and display performance of the display panel.

To address the technical problems mentioned above, the inventors have innovatively designed the following technical solutions. The specific implementation of the present application will be described in detail below with reference to the drawings. It should be noted that the defects in the solutions of the prior art mentioned above are the results of the inventors' practical experience and careful research. Therefore, the process of identifying the above technical problems and the solutions proposed in this embodiment to address these problems should be regarded as the contributions made by the inventors during the inventive process and should not be considered as technical content commonly known to those skilled in the art.

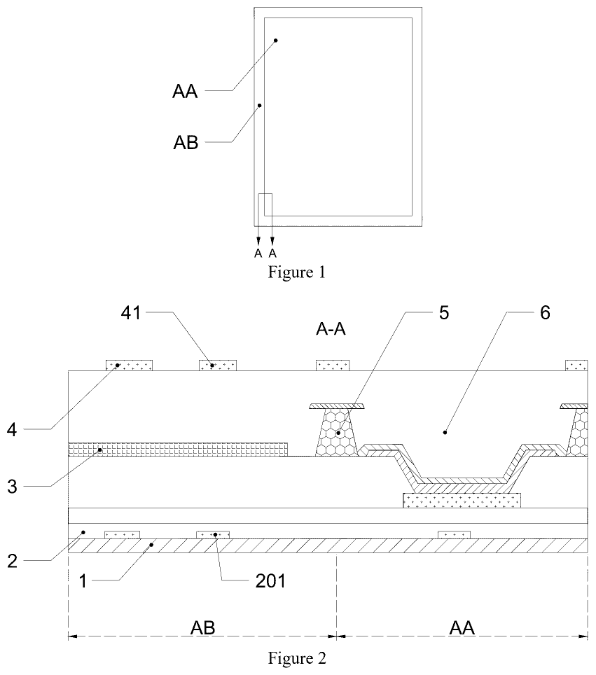

Please refer to FIG. 1 and FIG. 2. This embodiment provides a display panel, which includes a display area AA and a non-display area AB at least partially surrounding the display area AA. The display panel includes a substrate 1, an array signal layer 2, an isolation structure 5, a light-emitting unit 10, a touch layer 4, and a shielding layer 3.

The array signal layer 2 is located on one side of the substrate 1. The array signal layer 2 includes a plurality of signal traces 201, and at least one signal traces 201 is located in the non-display area AB.

The signal traces 201 can transmit signals in the display panel. For example, the signal traces 201 may be scan signal lines, reset signal lines, etc.

The isolation structure 5 is located on the side of the array signal layer 2 away from the substrate 1. The isolation structure 5 forms isolation openings 6, and at least part of the light-emitting unit 10 is located within the isolation openings 6.

The touch layer 4 is located on the side of the light-emitting unit 10 away from the substrate 1. The touch layer 4 includes touch traces 41, and at least one touch traces 41 is located in the non-display area AB.

The touch traces 41 may include touch receiving traces and touch transmitting traces. The touch receiving traces and touch transmitting traces can implement the touch function of the display panel.

The shielding layer 3 is located between the touch layer 4 and the array signal layer 2. The shielding layer 3 includes shielding traces, which are located in the non-display area AB. The orthographic projection of the touch traces 41 on the substrate 1 at least partially overlaps with the orthographic projection of the shielding traces on the substrate 1.

The shielding traces have a signal shielding function. Specifically, by arranging shielding traces between the touch traces 41 and the signal traces 201 in the non-display area AB of the display panel, and ensuring that the orthographic projection of the touch traces 41 on the substrate 1 at least partially overlaps with the orthographic projection of the shielding traces on the substrate 1, the signals from the signal traces 201 affecting the touch traces 41 can be shielded, and the signals from the touch traces 41 affecting the signal traces 201 can also be shielded. This reduces the mutual influence between the touch traces 41 and the signal traces 201 and mitigates crosstalk issues between the touch traces 41 and the signal traces 201.

Based on the above design, this embodiment, by arranging the shielding layer 3 between the touch layer 4 and the array signal layer 2 in the non-display area AB, can shield mutual interference between signals of the touch traces 41 and the signal traces 201, thereby improving the touch performance and display performance of the display panel.

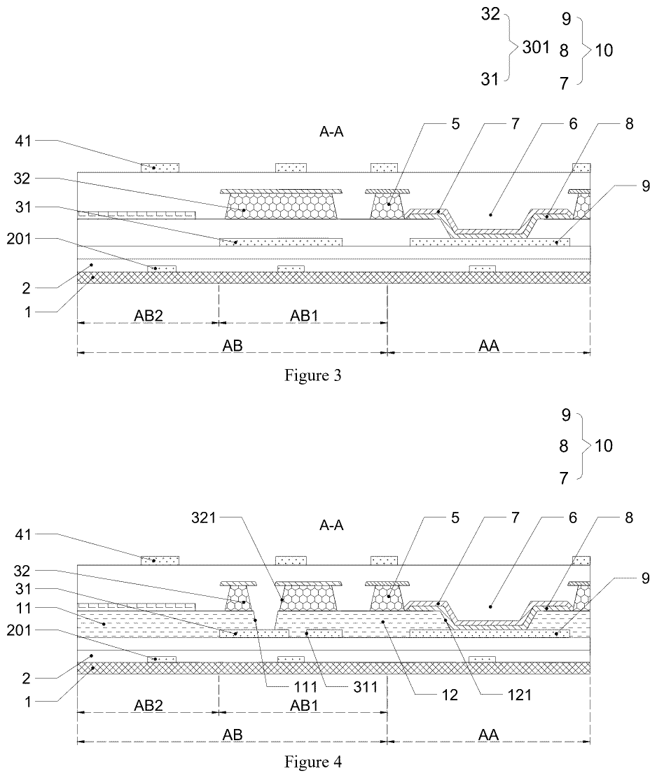

In some possible implementations, please refer to FIG. 3. The non-display area AB includes a first non-display area AB1 and a second non-display area AB2 located on the side of the first non-display area AB1 away from the display area AA. The first non-display area AB1 is provided with a first shielding structure 301, and the second non-display area AB2 is provided with a second shielding structure 302.

Optionally, the display panel includes a border area, and the non-display area AB includes the border area. The shielding traces are located in the border area.

Optionally, the orthographic projection of the first shielding structure 301 on the substrate 1 and the orthographic projection of the second shielding structure 302 on the substrate 1 overlap.

By arranging shielding traces in the border area of the display panel, mutual signal interference between the signal traces 201 and the touch traces 41 in the border area can be shielded.

In some possible implementations, please refer again to FIG. 3. Along the direction away from the substrate 1, the first shielding structure 301 includes a first shielding layer and a second shielding layer sequentially stacked. The first shielding layer includes first shielding traces 31, and the second shielding layer includes second shielding traces 32. Both the first shielding traces 31 and the second shielding traces 32 are located in the first non-display area AB1. The orthographic projections of the first shielding traces 31 and The orthographic projections of the second shielding traces 32 on the substrate 1 form a first pattern. The orthographic projection of the touch traces 41 located in the first non-display area AB1 on the substrate 1 at least partially overlaps with the first pattern.

Since the orthographic projection of the touch traces 41 located in the first non-display area AB1 on the substrate 1 at least partially overlaps with the first pattern, the first shielding traces 31 and the second shielding traces 32 can shield the touch traces 41 and the signal traces 201 in the first non-display area AB1, thereby reducing mutual interference between the touch traces 41 and the signal traces 201 in the first non-display area AB1.

Preferably, an orthographic projection of the touch traces 41 located in the first non-display area AB1 on the substrate 1 is located within the first pattern. In this way, the shielding effect of the first shielding traces 31 and the second shielding traces 32 on the touch traces 41 and the signal traces 201 located in the first non-display area AB1 is improved.

Preferably, referring again to FIG. 3, the material of the second shielding traces 32 is the same as that of the isolation structure 5 and is arranged in the same layer.

In this way, while forming the isolation structure 5 located in the display area AA, the second shielding traces 32 located in the first non-display area AB1 can be formed, thereby eliminating the need for a dedicated process to form the second shielding traces 32 and reducing the cost of forming the second shielding traces 32.

In some possible implementations, referring again to FIG. 3, the light-emitting unit 10 includes a first electrode 9, a light-emitting portion 8, and a second electrode 7 sequentially stacked along a direction away from the substrate 1.

The arrangement of the isolation structure 5 enables the display panel to form layers of light-emitting units 10 of different colors in different isolation openings 6 without requiring a fine metal mask. When forming the light-emitting material layer, the light-emitting material layer is interrupted by the isolation structure 5 to form multiple spaced-apart light-emitting portions 8. When forming the second electrode material layer, the second electrode material layer is interrupted by the isolation structure 5 to form multiple spaced-apart second electrodes 7. The isolation structure 5 includes a conductive material, and the second electrode 7 is electrically connected to the isolation structure 5. One first electrode 9, one light-emitting portion 8, and one second electrode 7 form one light-emitting unit 10. Here, the first electrode 9 may be an anode, and the second electrode 7 may be a cathode.

In this way, different light-emitting units 10 can be made independent of each other, thereby improving crosstalk between adjacent light-emitting units 10 and enhancing the display performance of the display panel. At the same time, due to the presence of the isolation structure 5, the light-emitting material layer and the second electrode layer of each color of the light-emitting unit 10 in the display panel can be fully prepared and then patterned, thereby eliminating the need for a fine metal mask and reducing the manufacturing cost of the display panel.

Optionally, the material of the first shielding traces 31 is the same as that of the first electrode 9 and is arranged in the same layer.

In this way, while forming the first electrode 9 located in the display area AA, the first shielding traces 31 located in the first non-display area AB1 can be formed, thereby eliminating the need for a dedicated process to form the first shielding traces 31 and reducing the cost of forming the first shielding traces 31.

In some possible implementations, referring to FIG. 4, along the thickness direction of the substrate 1, the first shielding traces 31 is provided with first exhaust holes 311, and the second shielding traces 32 is provided with second exhaust holes 321. The orthographic projection of the first exhaust holes 311 on the substrate 1 is located outside the orthographic projection of the second exhaust holes 321 on the substrate 1.

Optionally, the display panel further includes a first insulating layer 11 located between the first electrode 9 and the isolation structure 5. Along the thickness direction of the substrate 1, the first insulating layer 11 is provided with third exhaust holes 111.

The film layers on the side of the first shielding layer facing the substrate 1 contain a certain amount of moisture. If this moisture is not promptly discharged, it may affect the quality of the display panel. In this embodiment, by providing the first exhaust holes 311 on the first shielding traces 31, the second exhaust holes 321 on the second shielding traces 32, and the third exhaust holes 111 on the first insulating layer 11, the moisture in the film layers on the side of the first shielding layer facing the substrate 1 can be discharged sequentially through the first exhaust holes 311, the third exhaust holes 111, and the second exhaust holes 321. This allows timely discharge of moisture from the film layers on the side of the first shielding layer facing the substrate 1, thereby improving the quality of the display panel.

Additionally, by arranging the first exhaust holes 311 and the second exhaust holes 321 in a staggered manner, the orthographic projections of the first shielding traces 31 and the orthographic projections of the second shielding traces 32 on the substrate 1 form a continuous pattern, thereby providing more effective shielding for the touch traces 41 and the signal traces 201.

Preferably, referring again to FIG. 4, the third exhaust holes 111 is connected to the second exhaust holes 321. This facilitates the discharge of moisture through the third exhaust holes 111 and the second exhaust holes 321, further enabling timely discharge of moisture from the film layers on the side of the first shielding layer facing the substrate 1.

Preferably, the center of the orthographic projection of the third exhaust holes 111 on the substrate 1 coincides with the center of the orthographic projection of the second exhaust holes 321 on the substrate 1. This further enhances the timely discharge of moisture from the film layers on the side of the first shielding layer facing the substrate 1.

In some possible implementations, referring again to FIG. 4, the display panel further includes a pixel definition layer 12 located between the first electrode 9 and the isolation structure 5. The isolation structure 5 is located on a side of the pixel definition layer 12 away from the substrate 1. The pixel definition layer 12 includes a pixel opening 121 exposing at least a portion of the first electrode 9, and the pixel opening 121 is connected to the isolation opening 6.

Preferably, the pixel definition layer 12 extends from the display area AA to the non-display area AB, and the pixel definition layer 12 is reused as the first insulating layer 11.

In this way, while forming the pixel definition layer 12 located in the display area AA, the first insulating layer 11 located in the non-display area AB can be formed, thereby eliminating the need for a dedicated process to form the first insulating layer 11 and reducing the cost of forming the first insulating layer 11.

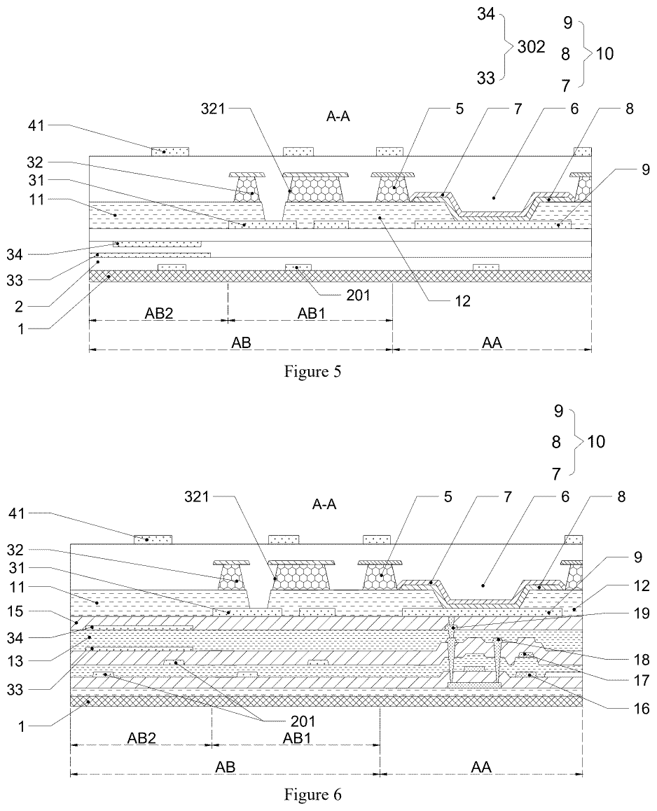

In some possible implementations, referring to FIG. 5, along the direction away from the substrate 1, the second shielding structure 302 includes a third shielding layer and a fourth shielding layer sequentially stacked. The third shielding layer includes third shielding traces 33, and the fourth shielding layer includes fourth shielding traces 34. Both the third shielding traces 33 and the fourth shielding traces 34 are located in the second non-display area AB2. The orthographic projections of the third shielding traces 33 and the fourth shielding traces 34 on the substrate 1 form a second pattern, and the orthographic projection of the touch traces 41 located in the second non-display area AB2 on the substrate 1 at least partially overlaps with the second pattern.

Since the orthographic projection of the touch routing 41 located in the second non-display area AB2 on the substrate 1 at least partially overlaps with the second pattern, the third shielding routing 33 and the fourth shielding routing 34 can provide shielding for the touch routing 41 and the signal routing 201 located in the second non-display area AB2, thereby reducing mutual interference between the touch routing 41 and the signal routing 201 located in the second non-display area AB2.

Preferably, the orthographic projection of the touch routing 41 located in the second non-display area AB2 on the substrate 1 is located within the second pattern. In this way, the shielding effect of the third shielding routing 33 and the fourth shielding routing 34 between the touch routing 41 and the signal routing 201 can be improved.

In some possible implementations, please refer to <FIG. 6>, the display panel further includes a first conductive layer 16, a second conductive layer 17, a third conductive layer 18, and a fourth conductive layer 19 sequentially stacked along a direction away from the substrate 1, wherein the third shielding routing 33 is located in the third conductive layer 18, and the fourth shielding routing 34 is located in the fourth conductive layer 19.

The display panel further includes a buffer layer and a semiconductor layer sequentially stacked between the substrate 1 and the first conductive layer 16, wherein the semiconductor layer includes a source region, a drain region, and a channel region, the first conductive layer 16 includes a gate and a first capacitor plate, the second conductive layer 17 includes a second capacitor plate, the first capacitor plate and the second capacitor plate form a capacitor, the third conductive layer 18 includes a drain and a source, the drain is electrically connected to the drain region, the source is electrically connected to the source region, the gate, the source, and the drain form a driving transistor, and the driving transistor is electrically connected to the first electrode 9. In this way, the signal of the driving transistor can be transmitted to the first electrode 9.

The signal routing 201 may be located in the first conductive layer 16 and/or the second conductive layer 17. While forming the first conductive layer 16 located in the display area AA, the third shielding routing 33 located in the non-display area AB can be formed, and while forming the fourth conductive layer 19 located in the display area AA, the fourth shielding routing 34 located in the non-display area AB can be formed, thereby eliminating the need for a dedicated process to form the third shielding routing 33 and the fourth shielding routing 34, and thus reducing the cost of forming the third shielding routing 33 and the fourth shielding routing 34.

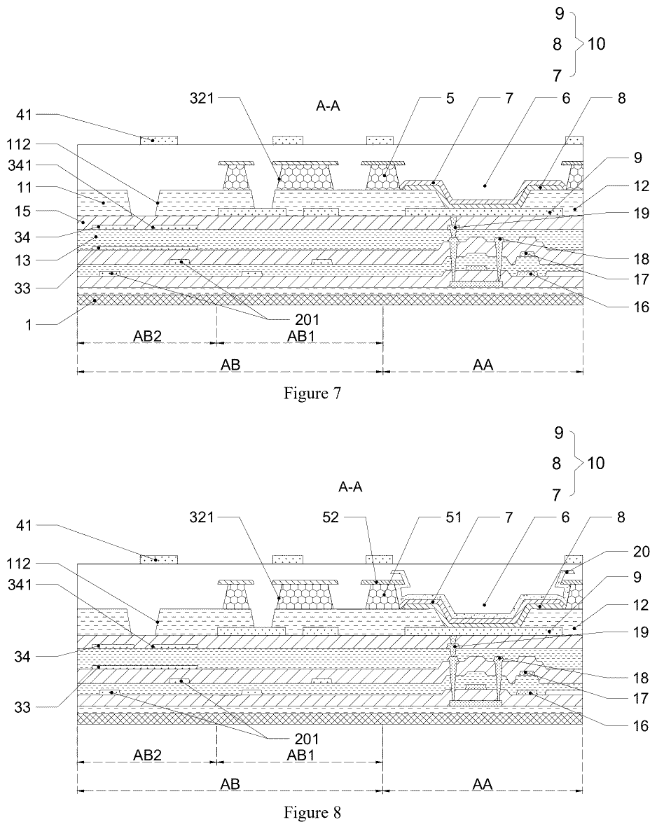

Preferably, please refer to <FIG. 7>, the display panel further includes a first insulating layer 11 located on a side of the fourth shielding layer away from the substrate 1, and fourth exhaust holes 112 is provided in the first insulating layer 11 along the thickness direction of the substrate 1.

Optionally, fifth exhaust holes 341 is provided in the fourth shielding routing 34 along the thickness direction of the substrate 1, and the orthographic projection of the fifth exhaust holes 341 on the substrate 1 at least partially overlaps with the orthographic projection of the fourth exhaust holes 112 on the substrate 1.

There is a certain amount of moisture in the film layer between the third shielding layer and the fourth shielding routing 34. In this embodiment, by providing the fifth exhaust holes 341 in the fourth shielding routing 34 and the fourth exhaust holes 112 in the first insulating layer 11, the moisture in the film layer between the third shielding layer and the fourth shielding routing 34 can be discharged sequentially through the fifth exhaust holes 341 and the fourth exhaust holes 112, thereby timely removing the moisture in the film layer between the third shielding layer and the fourth shielding routing 34, and thus improving the quality of the display panel.

Preferably, the center of the orthographic projection of the fifth exhaust holes 341 on the substrate 1 coincides with the center of the orthographic projection of the fourth exhaust holes 112 on the substrate 1. In this way, the moisture in the film layer between the third shielding layer and the fourth shielding routing 34 can be discharged more promptly.

Preferably, the display panel further includes a first planarization layer 13 and a second planarization layer 15 sequentially stacked along the direction away from the substrate 1, wherein the first planarization layer 13 extends from the display area AA to the non-display area AB, the first planarization layer 13 is located between the third shielding layer and the fourth shielding layer, and the second planarization layer 15 is located between the fourth shielding layer and the first insulating layer 11.

The material of the first insulating layer 11 includes an inorganic material, and the materials of the first planarization layer 13 and the second planarization layer 15 include an organic material. Moisture is easily transmitted in film layers including organic materials but not easily transmitted in film layers including inorganic materials. Therefore, the moisture in the first planarization layer 13 and the second planarization layer 15 can be discharged through the fifth exhaust holes 341 and the fourth exhaust holes 112.

Optionally, the orthographic projections of the first exhaust holes 311, the second exhaust holes 321, the third exhaust holes 111, the fourth exhaust holes 112, and the fifth exhaust holes 341 on the substrate 1 may all be rectangular, circular, or irregular in shape.

Optionally, the side lengths of the orthographic projections of the first exhaust holes 311, the second exhaust holes 321, the third exhaust holes 111, the fourth exhaust holes 112, and the fifth exhaust holes 341 on the substrate 1 are all greater than or equal to 5 μm and less than or equal to 30 μm, for example, they may be 5 μm, 10 μm, 15 μm, 20 μm, 25 μm, or 30 μm, etc.

In some possible implementations, please refer to <FIG. 8>, the display panel further includes an encapsulation unit 20 located on a side of the light-emitting unit 10 away from the substrate 1, at least a portion of the encapsulation unit 20 extends from the side of the isolation structure 5 facing the isolation openings 6 to a side of the isolation structure 5 away from the substrate 1, the encapsulation unit 20 is spaced apart on the side of the isolation structure 5 away from the substrate 1, and there is a gap between the encapsulation unit 20 on the side of the isolation structure 5 away from the substrate 1 and the side of the isolation structure 5 away from the substrate 1.

During the patterning process of the light-emitting unit 10, the first encapsulation layer is disconnected at the isolation structure 5 to form the encapsulation unit 20, and the encapsulation unit 20 can completely and independently encapsulate the corresponding light-emitting unit 10, thereby improving the display characteristics of the display panel.

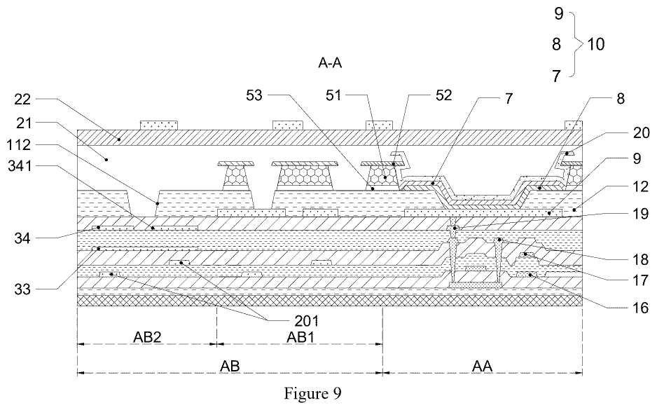

In some possible implementations, please refer to <FIG. 9>, the display panel further includes a second encapsulation layer 21 located on a side of the encapsulation unit 20 away from the substrate 1 and a third encapsulation layer 22 located on a side of the second encapsulation layer 21 away from the substrate 1, and the touch layer 4 is located on a side of the third encapsulation layer 22 away from the substrate 1.

Optionally, the materials of the encapsulation unit 20 and the third encapsulation layer 22 both include inorganic materials, and the material of the second encapsulation layer 21 includes an organic material.

For example, the encapsulation unit 20 and the third encapsulation layer 22 may be formed by chemical vapor deposition (CVD), and the second encapsulation layer 21 may be formed by ink-jet printing (IJP). The second encapsulation layer 21 and the third encapsulation layer 22 can provide a better encapsulation effect on the light-emitting unit 10, thereby further improving the encapsulation quality of the display panel.

In some possible implementations, please refer again to FIG. 8, the isolation structure 5 includes a first isolation portion 51 and a second isolation portion 52 sequentially stacked along a direction away from the substrate 1. An orthographic projection of a side of the first isolation portion 51 away from the substrate 1 onto the substrate 1 is located within an orthographic projection of the second isolation portion 52 onto the substrate 1.

Since the second isolation portion 52 is located on a side of the first isolation portion 51 away from the substrate, and a lateral width of the second isolation portion 52 is greater than a lateral width of the first isolation portion 51, the second isolation portion 52 causes the light-emitting functional layer and the second electrode 7 layer to break at the isolation structure 5. Thus, the isolation structure 5 formed by the first isolation portion 51 and the second isolation portion 52 can more easily enable independent encapsulation of each light-emitting unit 10.

Preferably, please refer again to FIG. 8, the second electrode 7 of the light-emitting unit 10 is electrically connected to the first isolation portion 51. The first isolation portion 51 includes a conductive material, and the second electrode 7 corresponding to the light-emitting unit 10 extends to contact a sidewall of the first isolation portion 51, thereby achieving electrical connection between the second electrode 7 corresponding to the light-emitting unit 10 and the first isolation portion 51.

Please refer again to FIG. 9, the isolation structure 5 further includes a third isolation portion 53 located on a side of the first isolation portion 51 facing the substrate 1, and the second electrode 7 of the light-emitting unit 10 is electrically connected to the third isolation portion 53.

The third isolation portion 53 includes a conductive material, and the second electrode 7 corresponding to the light-emitting unit 10 extends to contact a sidewall of the third isolation portion 53, thereby achieving electrical connection between the second electrode 7 corresponding to the light-emitting unit 10 and the third isolation portion 53.

Specifically, the material of the third isolation portion 53 includes molybdenum; and/or the material of the first isolation portion 51 includes aluminum; and/or the material of the second isolation portion 52 includes titanium. Thus, when the isolation structure 5 divides the second electrode 7 layer into separate second electrodes 7, the second electrodes 7 are more easily electrically connected to the first isolation portion 51 and/or the third isolation portion 53.

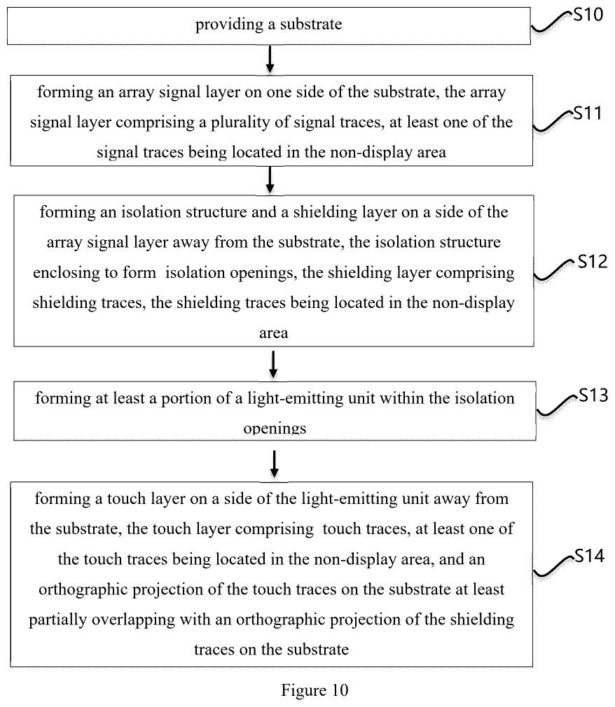

In some possible implementations, please refer to FIG. 10, the present application also provides a method for manufacturing a display panel. The display panel includes a display area AA and a non-display area AB at least partially surrounding the display area AA. The method includes:
S10: Providing a substrate 1.
S11: Forming an array signal layer 2 on one side of the substrate 1. The array signal layer 2 includes multiple signal traces 201, and at least one signal traces 201 are located in the non-display area AB.
S12: Forming an isolation structure 5 and a shielding layer 3 on a side of the array signal layer 2 away from the substrate 1. The isolation structure 5 encloses to form isolation openings 6. The shielding layer 3 includes shielding traces, and the shielding traces are located in the non-display area AB.
S13: Forming at least a portion of a light-emitting unit 10 within the isolation openings 6.
S14: Forming a touch layer 4 on a side of the light-emitting unit 10 away from the substrate 1. The touch layer 4 includes touch traces 41, and at least one touch traces 41 is located in the non-display area AB. An orthographic projection of the touch traces 41 onto the substrate 1 at least partially overlaps with an orthographic projection of the shielding traces onto the substrate 1.

The shielding traces have a signal shielding function. Specifically, by arranging the shielding traces between the touch traces 41 and the signal traces 201 in the non-display area AB of the display panel through the above method, and ensuring that the orthographic projection of the touch traces 41 onto the substrate 1 at least partially overlaps with the orthographic projection of the shielding traces onto the substrate 1, signals from the signal traces 201 affecting the touch traces 41 can be shielded, and signals from the touch traces 41 affecting the signal traces 201 can also be shielded. This reduces mutual interference between the touch traces 41 and the signal traces 201 and mitigates crosstalk issues between them.

In some possible implementations, the step of forming the isolation structure 5 and the shielding layer 3 on a side of the array signal layer 2 away from the substrate 1 includes:

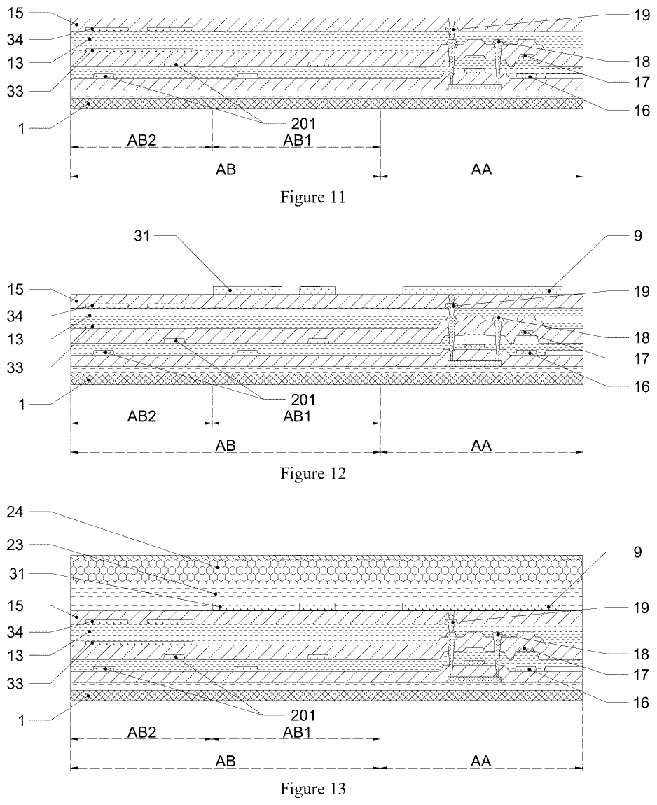

Please refer to FIG. 11, sequentially forming a third conductive layer 18, a first planarization layer 13, a fourth conductive layer 19, and a second planarization layer 15 on a side of the array signal layer 2 away from the substrate 1. The third conductive layer 18 includes a third shielding layer, and the fourth conductive layer 19 includes a fourth shielding layer.

The array signal layer 2 includes a first conductive layer 16 and a second conductive layer 17. While forming the third conductive layer 18 located in the display area AA, third shielding traces 33 located in the non-display area AB can be formed. While forming the fourth conductive layer 19 located in the display area AA, fourth shielding traces 34 located in the non-display area AB can be formed. This eliminates the need for dedicated processes to form the third shielding traces 33 and the fourth shielding traces 34, thereby reducing the cost of forming them.

Please refer to FIG. 12, forming a first electrode material layer on a side of the second planarization layer 15 away from the substrate 1, and patterning the first electrode material layer to form multiple first electrodes 9 located in the display area AA and a first shielding layer located in the non-display area AB including multiple first shielding traces 31.

While forming the first electrodes 9 located in the display area AA, the first shielding traces 31 located in the first non-display area AB1 can be formed. This eliminates the need for a dedicated process to form the first shielding traces 31, thereby reducing the cost of forming them.

Please refer to FIG. 13, sequentially forming a pixel definition material layer 23 and an isolation material layer 24 on a side of the first electrode 9 away from the substrate 1.

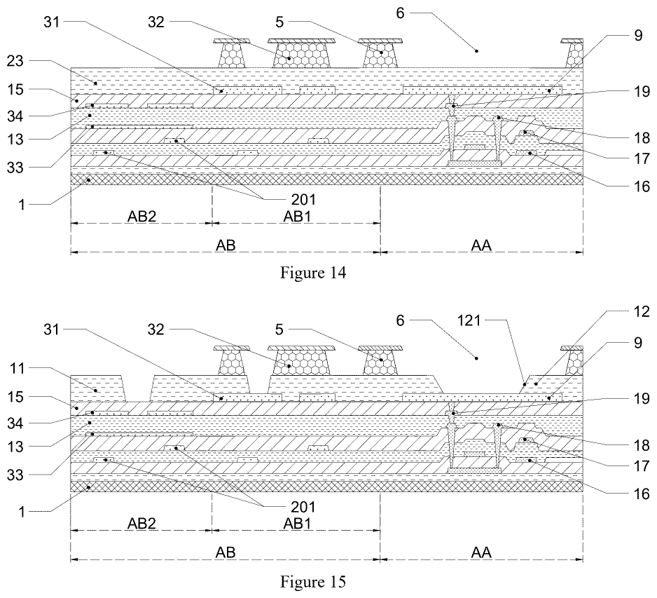

Please refer to FIG. 14, patterning the isolation material layer 24 to form the isolation structure 5 located in the display area AA and a second shielding layer located in the non-display area AB including multiple second shielding traces 32, respectively.

While forming the isolation structure 5 located in the display area AA, the second shielding traces 32 located in the first non-display area AB1 can be simultaneously formed, thereby eliminating the need for a dedicated process to form the second shielding traces 32 and consequently reducing the cost of forming the second shielding traces 32. Please refer to FIG. 15, where the pixel definition material layer 23 is patterned to form the pixel definition layer 12 in the display area AA and the first insulating layer 11 in the non-display area AB, respectively. While forming the pixel definition layer 12 located in the display area AA, the first insulating layer 11 located in the non-display area AB can be simultaneously formed, thereby eliminating the need for a dedicated process to form the first insulating layer 11 and consequently reducing the cost of forming the first insulating layer 11. In summary, the display panel formed by the above method can form the first shielding layer and the second shielding layer in the first non-display area AB1 at a lower cost, and form the third shielding layer and the fourth shielding layer in the second non-display area AB2 at a lower cost. This can more effectively shield the mutual signal crosstalk between the touch traces 41 and the signal traces 201 in the non-display area AB, thereby improving the touch performance and display performance of the display panel. In some possible implementations, the present application also provides an electronic device, which includes the display panel of the present application or a display panel prepared by the preparation method of the display panel of the present application. The electronic device may include devices with image processing capabilities, such as servers, personal computers, laptops, etc. Since the electronic device includes the display panel of the present application, the display quality of the electronic device is better. The technical features of the above embodiments can be combined arbitrarily. For the sake of brevity, not all possible combinations of the technical features in the above embodiments are described. However, as long as there is no contradiction in the combination of these technical features, they should be considered within the scope of this specification. The above-described embodiments merely represent several implementations of the present invention, and the descriptions thereof are specific and detailed, but should not be construed as limiting the scope of the patent. It should be noted that those of ordinary skill in the art can make various modifications and improvements without departing from the concept of the present invention, and these modifications and improvements fall within the protection scope of the present invention. Therefore, the protection scope of the patent of the present invention shall be subject to the appended claims.

1. A display panel, comprising a display area and a non-display area at least partially surrounding the display area, the display panel comprising:
a substrate;
an array signal layer located on one side of the substrate, the array signal layer comprising a plurality of signal traces, at least one of the signal traces being located in the non-display area;
an isolation structure located on a side of the array signal layer away from the substrate, the isolation structure enclosing to form isolation openings;
a light-emitting unit at least partially located within the isolation opening;
a touch layer located on a side of the light-emitting unit away from the substrate, the touch layer comprising touch traces, at least one of the touch traces being located in the non-display area; and
a shielding layer located between the touch layer and the array signal layer, the shielding layer comprising shielding traces located in the non-display area, an orthographic projection of the touch traces on the substrate at least partially overlapping with an orthographic projection of the shielding traces on the substrate.

2. The display panel according to claim 1, wherein the non-display area comprises a first non-display area and a second non-display area located on a side of the first non-display area away from the display area, the first non-display area is provided with a first shielding structure, and the second non-display area is provided with a second shielding structure;
the display panel comprises a border area, the non-display area comprises the border area, and the shielding traces are located in the border area;
an orthographic projection of the first shielding structure on the substrate and an orthographic projection of the second shielding structure on the substrate overlap.

3. The display panel according to claim 2, wherein along a direction away from the substrate, the first shielding structure comprises a first shielding layer and a second shielding layer sequentially stacked, the first shielding layer comprises first shielding traces, the second shielding layer comprises second shielding traces, an orthographic projection of the first shielding traces and an orthographic projection of the second shielding traces on the substrate form a first pattern, and an orthographic projection of the touch traces located in the first non-display area on the substrate at least partially overlaps with the first pattern.

4. The display panel according to claim 3, wherein the orthographic projection of the touch traces located in the first non-display area on the substrate is located within the first pattern.

5. The display panel according to claim 3, wherein a material of the second shielding traces are the same as a material of the isolation structure;
the second shielding traces and the isolation structure are disposed in a same layer.

6. The display panel according to claim 3, wherein the light-emitting unit comprises a first electrode, a light-emitting portion, and a second electrode sequentially stacked along a direction away from the substrate.

7. The display panel according to claim 6, wherein along a thickness direction of the substrate, first exhaust holes are provided on the first shielding traces, second exhaust holes are provided on the second shielding traces, and an orthographic projection of the first exhaust holes on the substrate are located outside an orthographic projection of the second exhaust holes on the substrate.

8. The display panel according to claim 7, further comprising a first insulating layer located between the first electrodes and the isolation structure, along the thickness direction of the substrate, third exhaust holes are provided on the first insulating layer;
the third exhaust holes are connected to the second exhaust holes;
a center of an orthographic projection of the third exhaust holes on the substrate coincide with a center of an orthographic projection of the second exhaust holes on the substrate.

9. The display panel according to claim 7, further comprising a pixel definition layer located between the first electrodes and the isolation structure, the isolation structure is located on a side of the pixel definition layer away from the substrate, the pixel definition layer comprises pixel openings exposing at least a portion of the first electrodes, and the pixel opening is connected to the isolation opening;
the pixel definition layer extends from the display area to the non-display area, and the pixel definition layer is reused as the first insulating layer.

10. The display panel according to claim 2, wherein along a direction away from the substrate, the second shielding structure comprises a third shielding layer and a fourth shielding layer sequentially stacked, the third shielding layer comprises third shielding traces, the fourth shielding layer comprise fourth shielding traces, an orthographic projection of the third shielding traces and an orthographic projection of the fourth shielding traces on the substrate form a second pattern, and an orthographic projection of the touch traces located in the second non-display area on the substrate at least partially overlaps with the second pattern.

11. The display panel according to claim 10, wherein the orthographic projection of the touch traces located in the second non-display area on the substrate are located within the second pattern.

12. The display panel according to claim 10, wherein the display panel further comprises a first conductive layer, a second conductive layer, a third conductive layer, and a fourth conductive layer sequentially stacked along a direction away from the substrate, the third shielding traces are located in the third conductive layer, and the fourth shielding traces are located in the fourth conductive layer.

13. The display panel according to claim 12, wherein the display panel further comprises a first insulating layer located on a side of the fourth shielding layer away from the substrate, along the thickness direction of the substrate, fourth exhaust holes are provided on the first insulating layer;
along the thickness direction of the substrate, fifth exhaust holes are provided on the fourth shielding traces, and an orthographic projection of the fifth exhaust holes on the substrate at least partially overlaps with an orthographic projection of the fourth exhaust holes on the substrate.

14. The display panel according to claim 13, wherein a center of the orthographic projection of the fifth exhaust holes on the substrate coincides with a center of the orthographic projection of the fourth exhaust holes on the substrate.

15. The display panel according to claim 1, wherein the signal traces are located in at least one of the first conductive layer or the second conductive layer.

16. The display panel according to claim 12, wherein the display panel further comprises a pixel definition layer located between the substrate and the isolation structure, the pixel definition layer comprising pixel openings exposing at least a portion of the first electrodes of the light-emitting unites; the pixel definition layer extends from the display area to the non-display area, and the pixel definition layer is reused as the first insulating layer; the display panel further comprises a first planarization layer and a second planarization layer sequentially stacked in a direction away from the substrate, the first planarization layer extends from the display area to the non-display area, the first planarization layer is located between the third shielding layer and the fourth shielding layer, and the second planarization layer is located between the fourth shielding layer and the first insulating layer.

17. A method for preparing a display panel, the display panel comprises a display area and a non-display area at least partially surrounding the display area, the method comprising:
providing a substrate;
forming an array signal layer on one side of the substrate, the array signal layer comprising a plurality of signal traces, at least one of the signal traces being located in the non-display area;
forming an isolation structure and a shielding layer on a side of the array signal layer away from the substrate, the isolation structure enclosing to form isolation openings, the shielding layer comprising shielding traces, the shielding traces being located in the non-display area;
forming at least a portion of a light-emitting unit within the isolation openings;
forming a touch layer on a side of the light-emitting unit away from the substrate, the touch layer comprising touch traces, at least one of the touch traces being located in the non-display area, and an orthographic projection of the touch traces on the substrate at least partially overlapping with an orthographic projection of the shielding traces on the substrate.

18. The method for preparing a display panel according to claim 17, wherein the step of forming the isolation structure and the shielding layer on the side of the array signal layer away from the substrate comprises:
sequentially forming a third conductive layer, a first planarization layer, a fourth conductive layer, and a second planarization layer on the side of the array signal layer away from the substrate, the third conductive layer comprising a third shielding layer, and the fourth conductive layer comprising a fourth shielding layer;
forming a first electrode material layer on a side of the second planarization layer away from the substrate, and patterning the first electrode material layer to form a plurality of first electrodes located in the display area and a first shielding layer located in the non-display area and comprising a plurality of first shielding traces;
sequentially forming a pixel definition material layer and an isolation material layer on a side of the first electrodes away from the substrate;
patterning the isolation material layer to form an isolation structure located in the display area and a second shielding layer located in the non-display area and comprising a plurality of second shielding traces, respectively;
patterning the pixel definition material layer to form a pixel definition layer located in the display area and a first insulating layer located in the non-display area, respectively.

19. An electronic device, the electronic device comprising a display panel, the display panel comprising:
a substrate;
an array signal layer located on one side of the substrate, the array signal layer comprising a plurality of signal traces, at least one of the signal traces being located in the non-display area;
an isolation structure located on a side of the array signal layer away from the substrate, the isolation structure enclosing to form isolation openings;
a light-emitting unit at least partially located within the isolation openings;
a touch layer located on a side of the light-emitting unit away from the substrate, the touch layer comprising touch traces, at least one of the touch traces being located in the non-display area;
a shielding layer located between the touch layer and the array signal layer, the shielding layer comprising shielding traces, the shielding traces being located in the non-display area, and an orthographic projection of the touch traces on the substrate at least partially overlapping with an orthographic projection of the shielding traces on the substrate.
